(19) United States
(12) Patent Application Publication
(10) Pub. No.: US 2026/0122785 A1
(43) Pub. Date: Apr. 30, 2026

(54) CIRCUIT BOARD CONNECTING STRUCTURE AND COMPUTING DEVICE

(71) Applicant: FOXCONN INTERCONNECT TECHNOLOGY LIMITED, Grand Cayman (KY)

(72) Inventor: CHIEN-WEN WANG, New Taipei (TW)

(21) Appl. No.: 18/963,638

(22) Filed: Nov. 28, 2024

(30) Foreign Application Priority Data
Oct. 28, 2024 (CN) 202411513198.3

(51) Int. Cl. H05K 1/14; H01R 12/71

(52) U.S. Cl. CPC H05K 1/144; H01R 12/716; H05K 2201/10189

(57) ABSTRACT

A circuit board connection structure includes a main circuit board, a main chip, and a first sub circuit board. The main circuit board includes an upper surface and a lower surface, with slots defining in each surface. The main chip and the first sub circuit board are respectively arranged on the upper and lower surfaces. The first surface is provided with at least one connector, and the second surface is provided with a connector plug. The connector plug is set in the slot to enable the first sub circuit board to be pluggable and unpluggable on the main circuit board. A computing device including the circuit board connection structure is also provided. By placing the main chip and the connector on opposite sides of the main circuit board, signal transmission path between the main chip and connector is effectively shortened.

### FIELD

The subject matter herein generally relates to a circuit board connecting structure and a computing device having the circuit board connecting structure.

### BACKGROUND

In era of artificial intelligence (AI), data centers play a crucial role. Data centers need to address a growing demand for computing, energy efficiency challenges, and sustainable development goals. Training and inference of AI algorithms require a large amount of data sets, so the data centers must be able to efficiently transmitting large amounts of data. With an increasing complexity of data center applications, a demand for network speed is also constantly growing. The speed of data center network upgrade and evolution is accelerating, from 1G, 10G, and 25G in the past to the widely used 100G today. However, in the face of large-scale artificial intelligence workloads, 400G and 800G transmission rates have become a key process in the evolution of data center networks. In a traditional general or high-speed PCB design, signal loss becomes one of the biggest challenges faced by designers during transmitting process of signal in components such as PCBs.

Therefore, there is room for improvement in the art.

### BRIEF DESCRIPTION OF THE DRAWINGS

Implementations of the present technology will now be described, by way of embodiments only, with reference to the attached figures.

FIG. 1 is a schematic view of a computing device according to a first embodiment of the present disclosure.

FIG. 2 is a top view of the computing device according to the first embodiment of the present disclosure.

FIG. 3 is a schematic view of a computing device according to a second embodiment of the present disclosure.

FIG. 4 is a top view of the computing device according to the second embodiment of the present disclosure.

FIG. 5 is a schematic view of a computing device according to a third embodiment of the present disclosure.

FIG. 6 is a top view of the computing device according to the third embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as coupled, whether directly or indirectly through intervening components, and is not necessarily limited to physical connections. The connection can be such that the objects are permanently coupled or releasably coupled. The term “comprising” when utilized, means “including, but not necessarily limited to”; it specifically indicates open-ended inclusion or membership in the so-described combination, group, series, and the like.

It should be noted that all directional indications (such as up, down, left, right, front, back, etc.) in the embodiments of present disclosure are only used to explain the relative position relationship and motion of each component in a specific posture (as shown in the attached figure). If the specific posture changes, directional indication will also change accordingly.

When a component is referred to as “fixed to”, “installed on”, or “arranged on” another component, it can be directly on another component or there can also be a centered component. The term ‘and/or’ used in the present disclosure includes all and any combination of one or more related listed items.

Embodiments of the present disclosure are described with reference to cross-sectional views, which are schematic views of idealized embodiments (and intermediate structures) of the present disclosure. Therefore, it is foreseeable that the shape of the illustration may differ due to manufacturing processes and/or tolerances. Therefore, the embodiments of the present disclosure should not be interpreted as limited to the specific shapes of the regions illustrated herein, but should include deviations in shape such as those resulting from manufacturing. The areas shown in the figure are only illustrative and their shapes are not intended to illustrate the actual shape of the device, nor to limit the scope of the present disclosure.

Some embodiments of the present disclosure will be described in detail with reference to the accompanying drawings. In non-conflicting situations, the following embodiments and their features can be combined with each other.

A conventional computing device typically has components such as a main chip and high-speed connectors on a same side of the main circuit board. The high-speed connectors are located around the main chip, while input/output ports (I/O ports) are set around the main circuit board. The high-speed connectors are connected to the input/output ports by cables. Signals from the main chip are transmitted downwards through the circuit board to the connectors, and then to the input/output ports by the cables.

The present disclosure provides a circuit board connection structure and a computing device, components such as a main chip and connectors are respectively installed on opposite sides of the main circuit board, shortening signal transmission path between the main chip and the connectors.

### First Embodiment

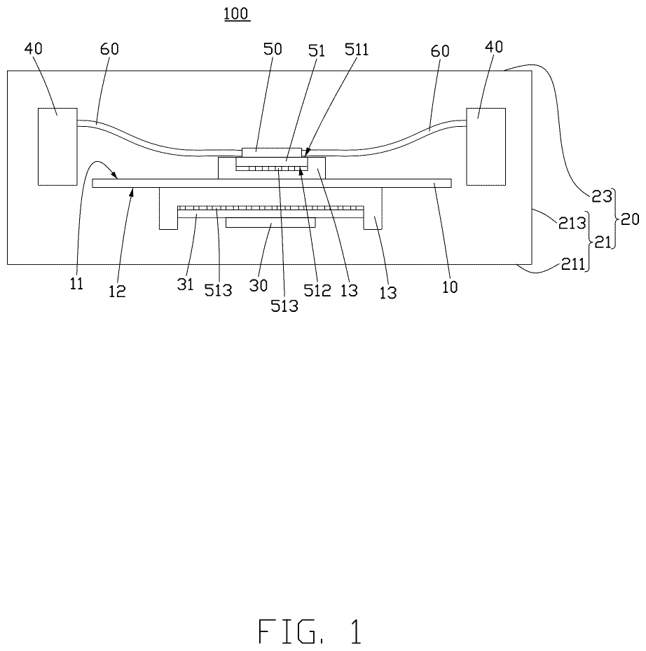

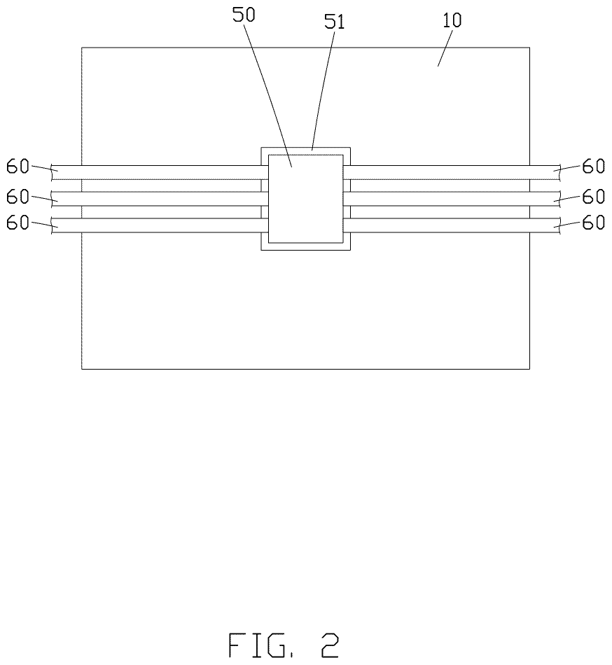

As shown in FIG. 1 and FIG. 2, a computing device 100 of the first embodiment of the present disclosure includes a circuit board connection structure. The circuit board connection structure includes a main circuit board 10 and components such as a main chip 30 and at least one connector 50 arranged on the main circuit board 10. The computing device 100 may be a switch, a server, etc., but is not limited to them.

The main circuit board 10 is a core component of the computing device 100 and also the largest printed circuit board in the computing device 100. A main function of the main circuit board 10 is to transmit various electronic signals. Multiple components in the computing device 100 can be connected by the main circuit board 10. In the present embodiment, the main circuit board 10 is a double-sided printed circuit board and includes an upper surface 11 and a lower surface 12 opposite to each other. Both the upper surface 11 and the lower surface 12 are covered with copper and wirings, and two wiring layers on the upper surface 11 and the lower surface 12 can establish a desired connection through vias in the main circuit board 10. In the embodiment, at least one slot 13 is defined in each of the upper surface 11 and the lower surface 12. A component matching the slot 13 can be inserted into the slot 13, and the component can connect to the main circuit board 10 in a pluggable manner.

As shown in FIG. 1, the main chip 30 is arranged on one of the upper surface 11 and the lower surface 12, and the first sub circuit board 51 is arranged on the other of the upper surface 11 and the lower surface 12. The first sub circuit board 51 includes a first surface 511 and a second surface 512 opposite to each other. The first surface 511 is provided with a connector 50, and the second surface 512 is provided with a connector plug 513 that matches the corresponding slot 13. The connector plug 513 is an electric conductive contact point for electrically connecting the slot 13 and the first sub circuit board 51. The connector plug 513 is inserted in the slot 13 to connect the first sub circuit board 51 to the main circuit board 10. The first sub circuit board 51 is insertable on the main circuit board 10. In the present embodiment, an area size of the first sub circuit board 51 is less than an area size of the main circuit board 10.

The method of setting the connector 50 on the first sub circuit board 51 can be one of the following, such as direct insertion connection, surface mount connection, hybrid connection, socket connection, spring connection, etc.

The direct insertion connection is the earliest connection method, also known as through-hole connection. In this method, pins of the connector are directly inserted into the through holes of the circuit board and fixed by soldering. The surface Mount (SMT) connection is a modern connection method in which the pins of the connector are directly attached to the surface of a circuit board and fixed by soldering. The surface mount connection has characteristics of small space occupation, light weight, and high production efficiency, but they are difficult to weld and maintain. The hybrid connection is a connection method that combines the advantages of direct insertion and surface mount connections. In this method, some pins are connected by direct insertion, while others pins are connected by surface mount. The hybrid connections have characteristics of high flexibility and reliability. The socket connection is a detachable connection method where the connector is inserted into a socket on the circuit board and secured with a buckle or screw. The socket connection is easy to replace and maintain, with good compatibility, but it is costly and occupies a large space. The spring connection is a method of connection that utilizes spring force, where pins of the connector make contact with the solder pads on the circuit board through the spring. The spring connection is easy to disassemble and suitable for situations that require frequent replacement or maintenance. The choice of appropriate connection method depends on specific application requirements, such as the need for frequent connector replacement, circuit board density, and ease of maintenance.

As shown in FIG. 1, the computing device 100 further includes a housing 20. The circuit board connection structure is arranged in the housing 20. The housing 20 provides protection for core components of the computing device (such as the circuit board connection structure). The housing 20 includes a frame 21 and a front cover 23. The frame 21 includes a bottom cover 211 and a side plate 213 vertically connected to the bottom cover 211. The bottom cover 211 and the side plate 213 form a receiving space. The front cover 23 is arranged opposite to the bottom cover 211, and the front cover 23 closes the receiving space. The side plate 213 is connected between the bottom cover 211 and the front cover 23. The front cover 23 is usually detachably mounted on the frame 21. When it is necessary to inspect and repair the computing device 100, the front cover 23 is removed from the frame 21. The main circuit board 10 is usually fixedly mounted on the bottom cover 211, with the upper surface 11 facing the front cover 23 and the lower surface 12 facing the bottom cover 211.

In the present embodiment, as shown in FIG. 1, the main chip 30 is arranged on the lower surface 12, and the first sub circuit board 51 and the connector 50 are arranged on the upper surface 11.

As shown in FIG. 1, there are multiple input/output ports 40 (I/O ports) arranged around the main circuit board 10. The input/output ports 40 can be between the side plate 213 and the main circuit board 10. The connector 50 connects the input/output ports 40 by cables 60. The main circuit board 10 is usually rectangular and includes four edges. The input/output ports 40 are located on at least two edges of the main circuit board 10. In the present embodiment, the input/output port 40 is set on opposite sides of the main circuit board 10.

Depending on a type of the connector 50 connected to the cable 60, the cable 60 includes at least one of conductive metal cable (such as copper cable), passive optical fiber cable, and active optical cable.

In the present embodiment, the computing device 100 is a cloud data switch, the connector 50 is a high-speed connector, and the cable 60 is a high-speed cable. The high-speed connector is an electronic connection device used for high-speed data transmission, specifically designed for transmitting high-frequency, high-speed data and signals. High-speed cable is a type of data transmission cable used for short distance connections, widely used in data centers and high-speed network environments.

In the present embodiment, as shown in FIG. 1, the main chip 30 is arranged on a second sub circuit board 31. The second sub circuit board 31 is pluggablely arranged on the main circuit board 10. The second sub circuit board 31 includes a surface facing the main circuit board 10 and a surface facing away from the main circuit board 10, wherein a connector plug 513 is provided on the surface facing the main circuit board 10. The connector plug 513 is inserted into the slot 13 on the lower surface 12 of the main circuit board 10. The main chip 30 is provided on the surface away from the main circuit board 10. Thus, the main chip 30 is also pluggable on the main circuit board 10. The method of setting the main chip 30 on the second sub circuit board 31 can be one of the following, such as direct insertion connection, surface mount connection, hybrid connection, socket connection, spring connection, etc.

In some embodiments, the main chip 30 is an ASIC chip, which is an application specific integrated circuit (ASIC) chip technology designed for specialized applications and is considered a type of integrated circuit designed for specific purposes in the integrated circuit industry. ASIC chip technology is developing rapidly, and the forwarding performance between ASIC chips can usually reach 1 Gbps or even higher, providing an excellent material foundation for the switching matrix.

In this way, in the computing device 100, the signal from the main chip 30 passes through the main circuit board 10, reaches the first sub circuit board 51, and then is transmitted to the connector 50 through the first sub circuit board 51. The connector 50 then transmits the signal to the input/output port 40 through the cable 60; Alternatively, the signal from input/output port 40 can be transmitted through cable 60 to connector 50, then through the first sub circuit board 51 to the main circuit board 10, and finally through the main circuit board 10 to reach the main chip 30.

Although not shown in the figure, it can be understood other electronic components such as heat dissipation components can also be installed on the main circuit board 10.

### Second Embodiment

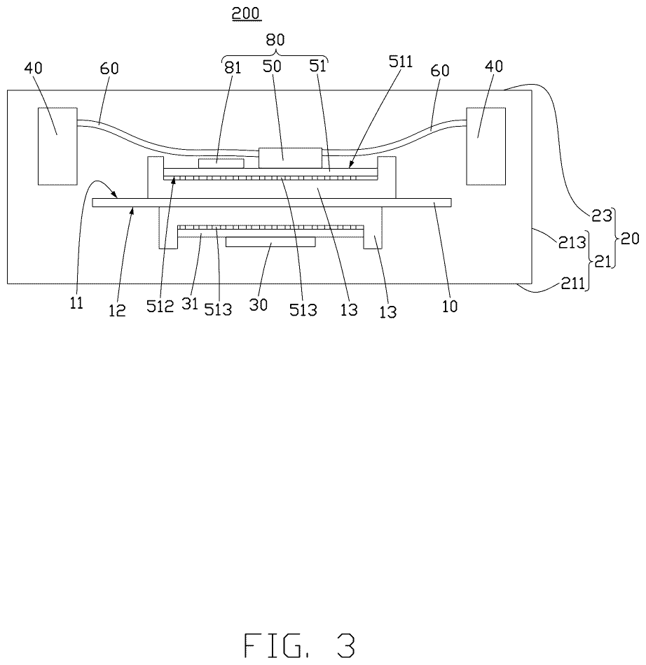

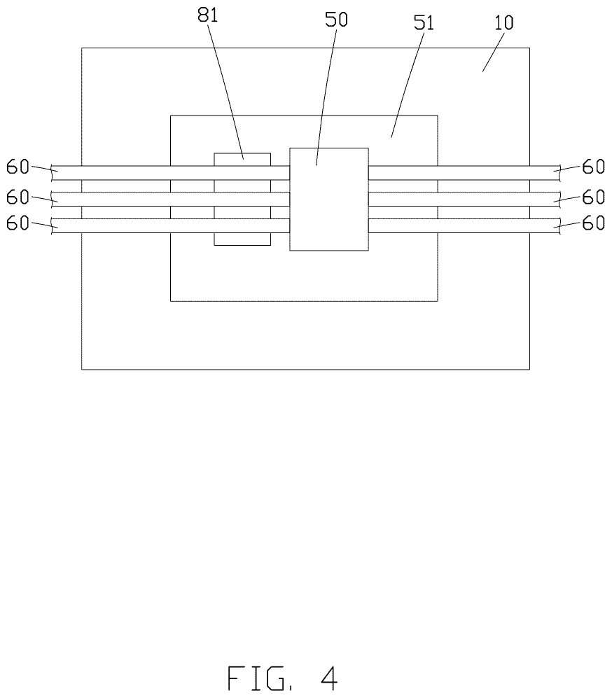

As shown in FIG. 3 and FIG. 4, in the computing device 200 of the second embodiment, the circuit board connection structure includes a main circuit board 10, and a main chip 30 and an optical engine module 80 arranged on the main circuit board 10, wherein the main chip 30 and the optical engine module 80 are arranged on opposite sides of the main circuit board 10.

The main circuit board 10 includes an upper surface 11 and a lower surface 12 opposite to each other. In this embodiment, the main chip 30 is arranged on the lower surface 12, and the optical engine module 80 is arranged on the upper surface 11. In other embodiments, the light engine module 80 is arranged on the lower surface 12, and the main chip 30 is arranged on the upper surface 11. The optical engine module 80 includes a first sub circuit board 51, an optical engine chip 81 mounted on the first sub circuit board 51, and a connector 50. The optical engine module 80 is a core component for implementing optical signal conversion in optical communication system, used for transmitting, receiving, and processing optical signals. The connector 50 is an optical engine connector.

The first sub circuit board 51 includes a first surface 511 and a second surface 512 opposite to each other. The first surface 511 is provided with the optical engine chip 81 and the optical engine connector 50. The second surface 512 is provided with a connector plug 513. The connector plug 513 is set in a slot 13 on the main circuit board 10, so that the first sub circuit board 51 is connected to the main circuit board 10 and can be plugged and unplugged on the main circuit board 10.

Correspondingly, there are multiple input/output ports 40 around the main circuit board 10, and the connector 50 is connected to the input/output ports 40 by multiple fiber optic cables 60.

The optical engine module 80 may also include other components. The first surface 511 of the first sub circuit board 51 is also provided with optical transceivers, optical modulators, optical paths, and driving circuits. The cables 60 connecting to the optical engine connector 50 include passive fiber optic cables 60.

### Third Embodiment

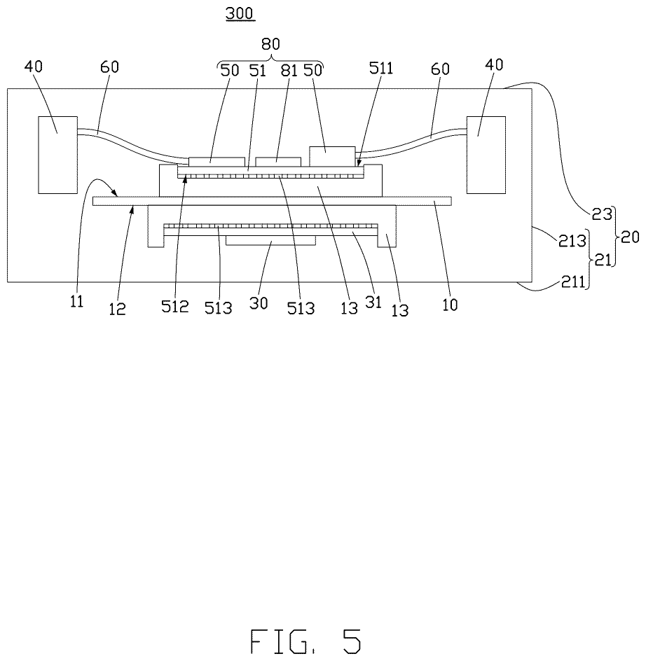

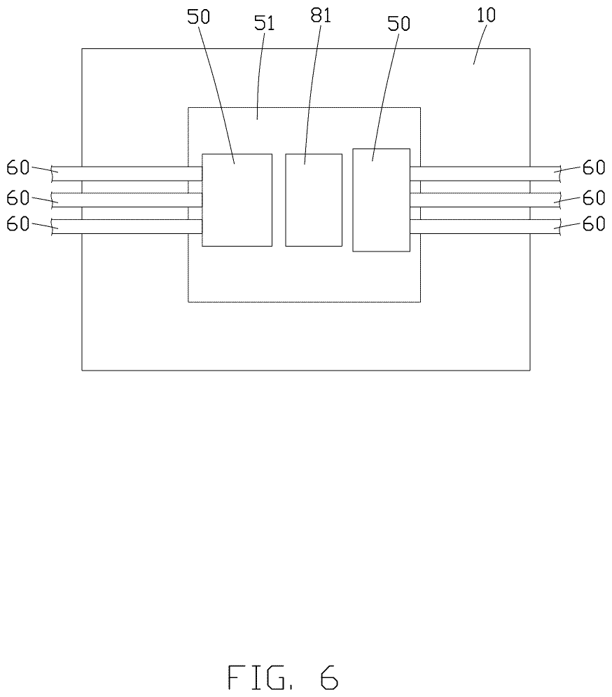

As shown in FIG. 5 and FIG. 6, in the computing device 300 of the third embodiment, the circuit board connection structure includes a main circuit board 10 and a main chip 30 and an optical engine module 80 arranged on the main circuit board 10. The main chip 30 and the optical engine module 80 are arranged on opposite sides of the main circuit board 10.

The main circuit board 10 includes an upper surface 11 and a lower surface 12 opposite to each other. The main chip 30 is located on the lower surface 12, and the light engine module 80 is located on the upper surface 11. The optical engine module 80 includes a first sub circuit board 51, an optical engine chip 81 mounted on the first sub circuit board 51, and connectors 50. The connectors 50 include an optical engine connector and other connectors.

The first sub circuit board 51 includes a first surface 511 and a second surface 512 opposite to each other. The first surface 511 is provided with the optical engine chip 81 and the connectors 50. The second surface 512 is provided with a connector plug 513. The connector plug 513 is set in a slot 13 on the main circuit board 10, so that the first sub circuit board 51 is connected to the main circuit board 10 and can be plugged and unplugged on the main circuit board 10. There are fiber optic cables 60 connected between the optical engine connector 50 and the corresponding input/output ports 40, and other cables 60 are connected between the other connector 50 and the corresponding input/output ports 40. The selection of the cable 60 depends on the type of the connector 50.

The circuit board connection structure of the computing device in the present disclosure effectively shortens the signal transmission path between the main chip 30 and the connector 50 by placing the main chip 30 and the connector 50 on opposite sides of the main circuit board 10. This design helps to shorten the optical path or circuit, reduce signal delay and loss, and thus improve data transmission speed and reliability. In addition, the connector 50 is arranged on the first sub circuit board 51, which is pluggable and unpluggable in the slot 13 of the main circuit board 10, making it easier to install the connector 50. When the connector 50 malfunctions or needs to be replaced, the first sub circuit board 51 can be removed from the main circuit board 10 for replacement, allowing for free replacement of the connector 50. Integrating the connector 50 and the main chip 30 on opposite sides of the main circuit board 10 makes it easier to install different heat dissipation components on the main circuit board 10, such as heat sinks, water-cooled boards, fans, and reduces heat concentration. All types of the connectors 50 are concentrated on a same side of the main circuit board 10, making it easier to manage the cables 60 connected to connectors 50 and reducing installation errors.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A circuit board connection structure comprising:
a main circuit board comprising an upper surface and a lower surface opposite to each other, and a slot defined in each of the upper surface and the lower surface;
a main chip on one of the upper surface and the lower surface; and
a first sub circuit board on another one of the upper surface and the lower surface, the first sub circuit board comprising a first surface and a second surface opposite to each other,
wherein at least one connector is arranged on the first surface, a connector plug is arranged on the second surface, the connector plug is inserted into the slot, and the first sub circuit board is pluggable and unpluggable on the main circuit board.

2. The circuit board connection structure of claim 1, further comprising a plurality of input/output ports around the main circuit board and a plurality of cables connected between the at least one connector and the plurality of input/output ports.

3. The circuit board connection structure of claim 2, wherein the plurality of cables comprises at least one of conductive metal cables, passive optical fiber cables, and active optical cables.

4. The circuit board connection structure of claim 2, further comprising an optical engine chip on the first surface, wherein the at least one connector comprises an optical engine connector, and the optical engine connector and corresponding input/output ports of the plurality of input/output ports are connected by fiber optic cables of the plurality of cables.

5. The circuit board connection structure of claim 4, wherein the at least one connector further comprises at least one other connectors connected to corresponding input/output ports of the plurality of input/output ports by cables of the plurality of cables.

6. The circuit board connection structure of claim 2, wherein an optical transceiver, an optical modulator, an optical path, and a driving circuit are on the first surface, and the plurality of cables comprise passive fiber optic cables.

7. The circuit board connection structure of claim 2, wherein each of the at least one connector is a high-speed connector, and each of the plurality of cables is a high-speed cable.

8. The circuit board connection structure of claim 1, wherein the main chip is set on a second sub circuit board, and the second sub circuit board is pluggable and unpluggable in the slot of the main circuit board.

9. A computing device comprising:
a housing; and
a circuit board connection structure in the housing, the circuit board connection structure comprising:
a main circuit board comprising an upper surface and a lower surface opposite to each other, and a slot defined in each of the upper surface and the lower surface;
a main chip on one of the upper surface and the lower surface; and
a first sub circuit board on another one of the upper surface and the lower surface, the first sub circuit board comprising a first surface and a second surface opposite to each other,
wherein at least one connector is arranged on the first surface, a connector plug is arranged on the second surface, the connector plug is inserted into the slot, and the first sub circuit board is pluggable and unpluggable on the main circuit board.

10. The computing device of claim 9, wherein the circuit board connection structure further comprises a plurality of input/output ports around the main circuit board and a plurality of cables connected between the at least one connector and the plurality of input/output ports.

11. The computing device of claim 10, wherein the plurality of cables comprises at least one of conductive metal cables, passive optical fiber cables, and active optical cables.

12. The computing device of claim 10, wherein the circuit board connection structure further comprises an optical engine chip on the first surface, the at least one connector comprises an optical engine connector, and the optical engine connector is connected to corresponding input/output ports of the plurality of input/output ports by fiber optic cables of the plurality of cables.

13. The computing device of claim 12, wherein the at least one connector further comprises at least one other connector connected to corresponding input/output ports of the plurality of input/output ports by cables of the plurality of cables.

14. The computing device of claim 10, wherein an optical transceiver, an optical modulator, an optical path, and a driving circuit are on the first surface, and the plurality of cables comprise passive fiber optic cables.

15. The computing device of claim 10, wherein each of the at least one connector is a high-speed connector, and each of the plurality of cables is a high-speed cable.

16. The computing device of claim 9, wherein the main chip is set on a second sub circuit board, and the second sub circuit board is pluggable and unpluggable in the slot of the main circuit board.

17. The computing device of claim 9, wherein the computing device is a switch.
